(19) United States
(12) Patent Application Publication
(10) Pub. No.: US 2001/0026623 A1
(43) Pub. Date: Oct. 4, 2001

(54) Remote Broadcasting System

(76) Inventor: Mr. Duane A. Erwin, St. Cloud, MN (US)

Correspondence Address: Al Watkins, Quill & Disc Incorporated, 30844 NE 1st Avenue, St. Joseph, MN, 56374, US, quill@qwest.net, 320-363-7296, 320-363-7396

(21) Appl. No.: 09/690,662

(22) Filed: Oct. 17, 2000

(51) Int. Cl. H05K 11/02; H04R 27/00

(52) U.S. Cl. 381/82; 381/86

(57) ABSTRACT

### ABSTRACT OF THE DISCLOSURE

A remote broadcast vehicle does not require any setup time, may remain fully enclosed and locked while in operation, and which prevents the ingress of moisture and other weather. The vehicle may includes a player for pre-recorded audio programs, a radio broadcast station receiver, wireless microphone and wireless remote control, mixer, cross-over, amplifiers and speaker assemblies. The system may further be used to up-link a program to a base radio station, and provide full programming capability. Additionally, a tuned port speaker system is disclosed for broadcasting low frequencies through the vehicle wall. Several different vehicle embodiments are illustrated.

### BACKGROUND OF THE INVENTION

### 1. FIELD OF THE INVENTION

The present invention pertains generally to vehicle-supported electrical audio signal processing systems. More specifically, the invention comprises a complete remote broadcasting system built into and advantageously integrated with features relatively unique to a vehicle, including local power and amplification, limited access and built-in security, signal source switching between public address and various audio sources, and output to selectable internal and external speakers and also through a remote transmitter. In one more specific embodiment, a novel tuned-port speaker is provided in combination with the vehicle-supported remote broadcast system.

### 2. DESCRIPTION OF THE RELATED ART

In the broadcasting field, two general systems have been implemented to serve the needs of on-location broadcasting. The first prior art system uses a trailer to transport audio components to a site. At the site, the audio components are unpacked and connected electrically as required. Typically, a gasoline engine electrical generator is included as one of the components, and the generator must be started to provide electrical energy to the broadcasting components. This system has several inherent disadvantages. First of all, the components used for on-location broadcasting generally include several massive loudspeakers. To move these loudspeakers may require several strong persons, which means that these systems not only require the DJ or announcer, but also require one or more additional persons just to unpack and pack the gear. A second disadvantage is the time required to pack and unpack, which is wasted time. The gear is also not easily anchored after it is unpacked, meaning the DJ must remain close to the gear and must pay close attention thereto, in order to prevent theft or vandalism. Not only are the components of a broadcast system expensive, in this trailer system the wiring is also exposed and readily cut or damaged. Consequently, the DJ or another person must stand guard over the equipment during the entire broadcast session. Unfortunately, the generator must be run to provide power to the equipment. Since the DJ must stay close to the equipment, the noise from the generator presents undesirable background noise and potential electrical interference which the DJ cannot escape. Finally, the equipment is exposed to the vagaries of an outdoor environment during the broadcast, requiring careful wiring and weatherproof equipment.

In another prior art system, speakers may be provided for placement on top of a vehicle, out of a window, or out the rear doors of a van, pick-up or the like. In these systems, the vehicle must be stationary or moving relatively slowly, to prevent dislodging or damage to the equipment. Furthermore, the equipment is still exposed to theft and vandalism, and also the vagaries of weather, as in the trailer configuration.

Loudspeakers have been used in combination with vehicles for almost as long as vehicles have existed. The broader concept of a loudspeaker mounted through the side of a vehicle is illustrated, for example, in U.S. patent 3,043,912 to De Laney. Delaney discloses an automobile intercom that mounts a speaker into a wooden or plastic block and ducts the air through a hole in the vehicle side wall. Additional relevant documents include 2,110,358 to Dreisback; 4,009,375 to White et al; 4,192,216 to Wait; 4,701,627 to Gambuti et al; 5,170,435 to Rosen et al; 5,228,090 to Marler; 5,263,756 to Gaspar; 5,790,065 to Yaroch; 5,790,947 to Dieringer; 5,917,920 to Humphries; and 6,055,417 to Hill et al. Nevertheless, none of these systems integrate a high quality speaker system into a vehicle for broadcasting exterior to the vehicle, nor do these patents illustrate the integration of a broadcasting system into a mobile vehicle. What is desirable then is to integrate the audio components more closely with a vehicle, to take advantage of the benefits inherent in the vehicle, such as the secure exterior which provides protection from weather and also theft or vandalism.

### SUMMARY OF THE INVENTION

In a first manifestation the invention is a tuned-port electrical audio processing system for processing a plurality of electrical source signals and converting said plurality of electrical source signals into an audio broadcast. The electrical audio processing system is transported by a vehicle having an interior compartment surrounded by a vehicle exterior which protects the interior compartment from the vagaries of moisture, mud, dirt and debris during transport. The audio processing system has a means for providing electricity, a means for selecting an input signal from a plurality of sources, a means for amplifying the selected signal, a means for dividing the input signal into a plurality of frequency segregated output components, a means for converting one of the frequency segregated output components into a low frequency audible sound wave, and a means for selectively conducting low frequencies within the sound wave through the vehicle exterior while attenuating frequencies other than low frequencies. The tuned-port system conducts low frequencies to the vehicle exterior without coupling to the vehicle, thereby avoiding the generation of extraneous rumbling and rattling from various vehicle component resonances.

In a second manifestation, the invention is a full-feature, secure remote broadcast vehicle which is continuously setup. The vehicle is simultaneously secured against theft and vandalism in operation and while idle, thereby allowing an operator to leave the immediate vicinity of the vehicle and not risk loss due to theft or vandalism. A plurality of electro-audio components are mounted within the vehicle, such as a CD, tape or DVD player, a radio broadcast receiver, a wireless microphone transmission receiver, an electrical generator, a remotely controlled selector switch, a loudspeaker, and a port coupled from the loudspeaker through the vehicle exterior which emanates audible sound waves exterior to the vehicle and which selectively enhances a narrow bandwidth of the audible sound wave. A microphone and a remote control are also provided which allow an operator to variably control source, including sounds picked up by the microphone, and volume of the audible sound wave for broadcast from the vehicle.

In a third manifestation, the invention is the combination of a speaker for converting electrical signals to audible sounds and a vehicle having an exterior body forming an enclosed space. A cross-over divides the electrical signals into a low frequency component and a high frequency component. A speaker housing encloses the speaker and blocks emanation of audible sounds directly from said speaker into an ambient exterior to said speaker housing. A tuned port selectively transmits a limited bandwidth of the audible sounds from the speaker housing through the exterior vehicle body.

### OBJECTS OF THE INVENTION

A first object of the invention is to provide a remote broadcast vehicle which does not require any setup time to operate on-location, and which may be used while in motion as well as at rest. A second object of the invention is for the remote broadcast vehicle to remain fully enclosed and secured while in operation, without unacceptable degradation of the sound produced and emanating from the vehicle. A third object of the invention is to enable an announcer or DJ to move around separate from the remote broadcast vehicle, while still remaining in control of the sounds emanating therefrom. Another object of the invention is to provide a tuned port speaker system which permits broadcasting audio information at high volumes and power outputs through a vehicle wall without initiating any resonance within the vehicle itself.

### BRIEF DESCRIPTION OF THE DRAWINGS

Figure 1 illustrates a preferred embodiment remote broadcasting system designed in accord with the teachings of the present invention from a side plan view.

Figure 2 illustrates the preferred remote broadcasting system of figure 1 from a schematic top plan view with the roof removed, while figure 3 illustrates the remote broadcasting system from an end schematic view looking into the back of the van.

Figure 4 illustrates a preferred source of power for the preferred remote broadcasting system.

Figure 5 illustrates diagrammatically one preferred combination of audio components used in the implementation of the preferred remote broadcasting system.

Figure 6 illustrates by block diagram the various components used in the preferred combination of figure 5.

Figure 7 illustrates diagrammatically an alternative combination of audio components used in the implementation of the preferred remote broadcasting system.

Figure 8 illustrates an alternative embodiment deluxe remote broadcasting system designed in accord with the teachings of the present invention from a side plan view.

Figure 9 illustrates the alternative embodiment remote broadcasting system of figure 8 from a schematic top plan view with the roof removed, while figure 10 illustrates the remote broadcasting system from an end schematic view looking into the back of the truck.

Figure 11 illustrates a preferred embodiment ported loudspeaker designed in accord with the teachings of the present invention.

Figure 12 illustrates a second alternative embodiment remote broadcasting system designed in accord with the teachings of the present invention from a side plan view, and from an end plan view in figure 13.

### DESCRIPTION OF THE PREFERRED EMBODIMENT

A preferred full-feature remote broadcast system 100 is most preferably assembled from a pre-manufactured vehicle 110. Vehicle 110 will most preferably be a van, truck, pick-up truck or the like, but it will be understood that other vehicles may be used, including passenger vehicles and trailers without departing from the full scope of the invention. Nevertheless, vehicle 110 will most preferably provide adequate space for and access to each of the components described herein below, and for this a larger vehicle is most preferred. In addition, a larger vehicle provides extra cargo space, when additional persons, gear, merchandise or the like must be transported. Access is provided through a door 120 as is known in the vehicle industry.

Speaker assemblies 560 and 560' may be mounted into the side wall of vehicle 110, and may pass through the body panels or may alternatively pass through windows, where the vehicle has windows at the desired locations. Most preferably, speaker assembly 560 may be used to convert electrical signals into audible sound waves which represent one channel of a stereo program, for example the left channel. Similarly, speaker assembly 560' will produce audible sound waves from the other channel, for example the right channel. Speaker assemblies 560 and 560' will most preferably be separated physically from each other by as much space as practical, given the limitations of vehicle 110, to preserve the full three-dimensional auditory effect of a stereo broadcast as much as possible. Once again, a larger vehicle 110 such as a van or truck facilitates this separation. Speaker assemblies 560 and 560' will most preferably be weatherproof speakers having a high quality audible reproduction characteristic. Nevertheless, the specific geometries illustrated herein for these assemblies is not critical to the workings of the invention. Speakers which provide a desired durability, weather resistance, physical dimension and quality of sound reproduction will be acceptable regardless of their construction or type, within reason.

Speaker assembly 570 is a sub-woofer driver and tuned port which conveys audible sound waves to the exterior of vehicle 110. Placement of assembly 570 is not consequential to the invention, owing to the non-directional nature of low-frequency sounds. For the purposes of this disclosure, low frequency sounds will be understood to be those frequencies which are non-directional and which are within the range of significant mechanical resonance of vehicle body panels and parts. Generally, these frequencies are below about 100 Hertz, and more commonly are below 60 Hertz. Many sub-woofers operate at even lower frequencies, below 30 Hertz and even some lower still. The exact frequency range for these low-frequency sounds will be readily determined by the system designer as will be apparent when considered in light of the present disclosure. Most preferably, the tuned port will attenuate frequencies outside of a relatively narrow band of low-frequency sounds, while simultaneously reinforcing the low-frequency sounds within the narrow band of frequencies. The design of critical dimensions used in such ports is known in the loudspeaker industry, and will not be repeated herein, though it will be understood that a remote broadcast system 100 will require such design.

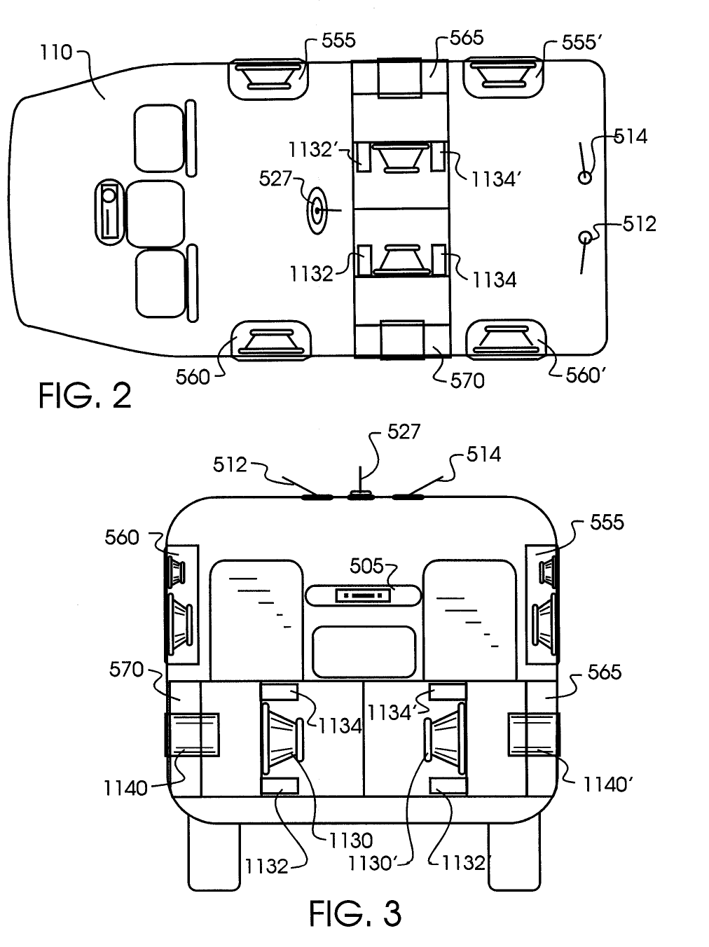

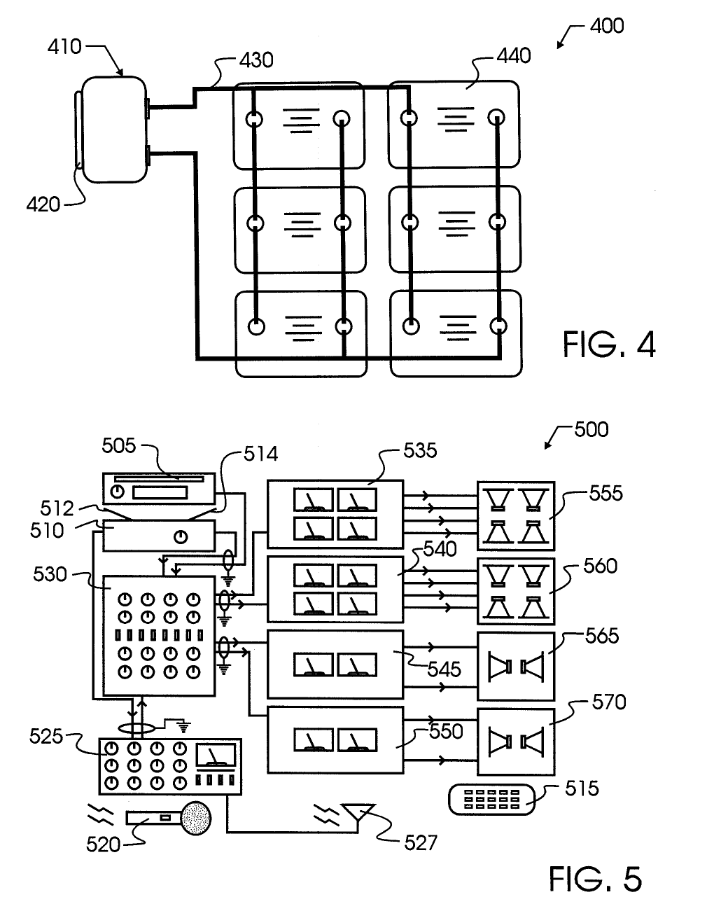

Figures 2 and 3 illustrate preferred remote broadcast system 100 from a top plan view with the roof removed and from an end plan view with the back doors removed, respectively, each having features removed strictly for illustrative purposes. As can be seen therein, ported speaker assembly 570 may pass through not just one side of vehicle 110, but will also most preferably include a second similar ported speaker assembly 565 for broadcasting from the opposite side of vehicle 110. Similar speaker assembly pairs are provided in speaker assemblies 555 and 555'. The exact number, spacing and directional orientation of the various speaker assemblies is not critical to the operation of the invention, though the orientation and spacing illustrated herein is most preferred to provide a broadcast signal from both sides of vehicle 110. Nevertheless, it will be understood that only one set of speaker assemblies pointing in a single direction may be adequate for some applications, while others may require speakers pointing in every direction, or at least from three of the four sides of vehicle 110. Once again, those skilled in the art will recognize the various alternatives.

Speaker assembly 570 includes a dual-resonance chamber design having ports 1132 and 1134 which are tuned to a center frequency of between 20 and 60 Hertz. In larger vehicles 110, this design can accommodate lower frequencies and will be tuned to a center frequency closer to 20 Hertz, while in smaller compartments ports 1132 and 1134 will need to be tuned to frequencies closer to 60 Hertz. Port 1140 may be similarly tuned to resonant frequencies in the 40 to 100 Hertz range, thereby broadening the bandwidth of the tuned port.

Several antennas are provided in remote broadcast system 100, including an antenna 527 for an up-link to a base broadcasting station. This up-link may utilize a component known as a Marti box, or other suitable gear. Antenna 527 will facilitate this transmission. Antennas 512 and 514 are provided for communication between a wireless control and/or microphone and audio gear within vehicle 110 which will be described in greater detail hereinbelow. Once again, the exact placement of antennas 512, 514 and 527 is not critical to the invention, so long as the antennas do not physically or electrically interfere with each other.

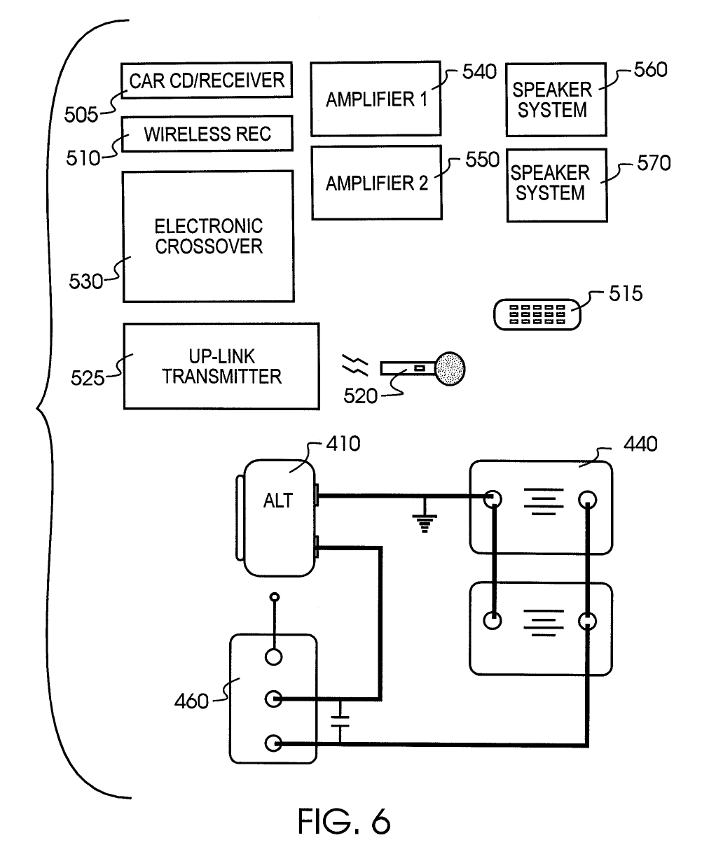

The preferred electrical power source 400 includes an alternator 410 having a pulley 420 for driving engagement with a belt as is known in the vehicle industry. However, most preferably alternator 410 is completely independent from the electrical system provided at the factory for vehicle 110, and will instead only provide power through cabling 430 to the audio components of the remote broadcast system 100. This reduces electrical interference and noise, while also ensuring that vehicle 110 will start and operate even if the full capacity of battery 400 electrical storage is consumed during a broadcasting session. Where vehicle 110 is a trailer, the electrical power must be provided through a trailer hitch electrical connection. As an alternative shown in figure 6, the existing alternator can be used. In this case, it will generally be desirable to incorporate a diode isolator 460 to allow the current from alternator 410 to be split between the factory vehicle wiring and wiring for system 100 without direct connection therebetween. Additional noise filters may also be provided as required in power source 400.

Figure 5 illustrates diagrammatically the various audio components 500 used in preferred remote broadcast system 100, though it will be understood by those skilled in the art that various components may be added or removed for the specific needs of a particular designer. Figure 6 also illustrates each of these components by block diagram. A player 505 designed for reproducing pre-recorded audio information may be part of vehicle 110 original equipment, or may be added as a custom feature. Player 505 may include one or more of the commercial players, including such devices as audio CD players, tape players, DVD players and the like. A receiver 510 for wireless information such as might be transmitted by wireless microphone 520 and wireless remote control 515 includes two antennas 512 and 514 previously discussed. Wireless radio connections from microphone 520 and remote control 515 may be analog or digitally encoded, though an analog link is simpler and available for lower cost. Where an analog signal is incorporated, a twin-diversity type signal transmission is preferred which uses two simultaneous channels to prevent drop-outs from occurring. Up-link 525 is most preferably a Marti unit, and includes antenna 527. The outputs from each of these various components 505 - 527 are fed to a cross-over 530 which is designed to select from the various audio input sources and split the selected signal(s) into frequency and channel segregated outputs. These outputs are then passed through amplifiers 535 - 550, where the electrical signal power is amplified and impedance matched to the various speakers of speaker assemblies 555 - 570.

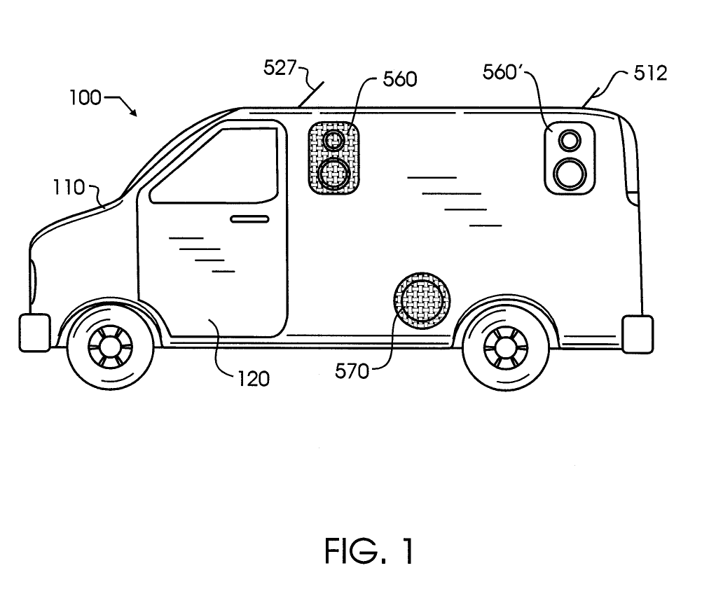

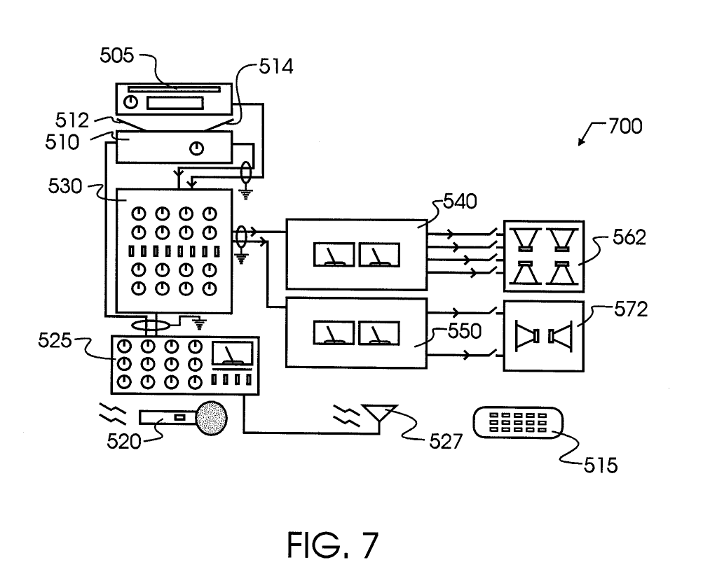

An alternative audio component set-up 700 is illustrated in figure 7. Noteworthy here is the removable connections between speaker assemblies 562, 572 and amplifiers 540, 550. The application of this configuration is found where there is not adequate space within vehicle 110 to provide built-in speaker assemblies as shown in figure 1, for example. In these instances, separate mounts and electrical connections may be provided for speaker assemblies 562, 572, and the electrical connections must be removable. In addition, there is a two-way connection between up-link 525 and cross-over 530. This two-way connection allows the further possibility for the entire broadcast from a base radio station to be provided by remote broadcasting system 100 and transmitted through up-link 525 to the base radio station for re-broadcasting. Pre-recorded audio information may be passed from player 505 through cross-over 530 and into up-link 525, along with audible information from the announcer or DJ. In this instance, an audio mixing board separate from cross-over 530 may also be provided as is normally implemented in a base radio station. This system would, however, most preferably still allow for remote audio broadcasting without using up-link 525, and allow a remote DJ presentation.

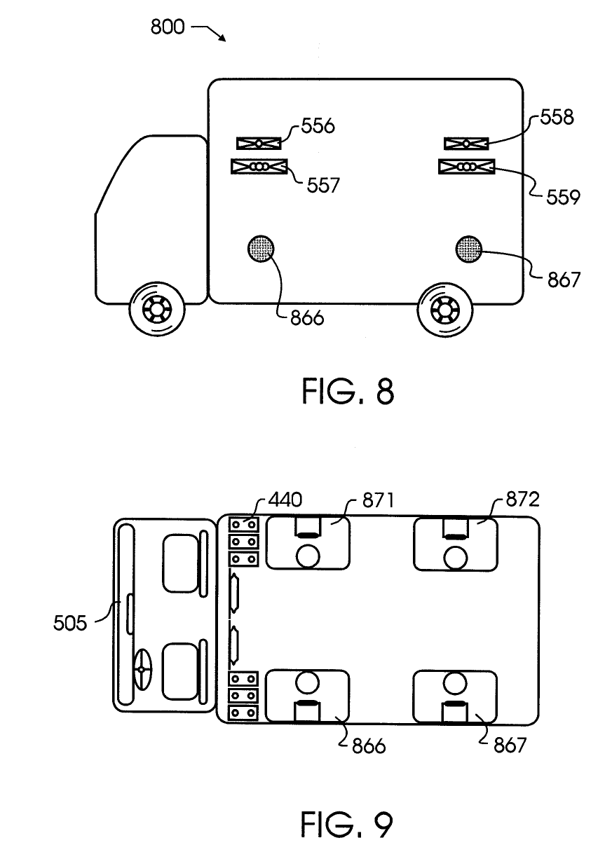

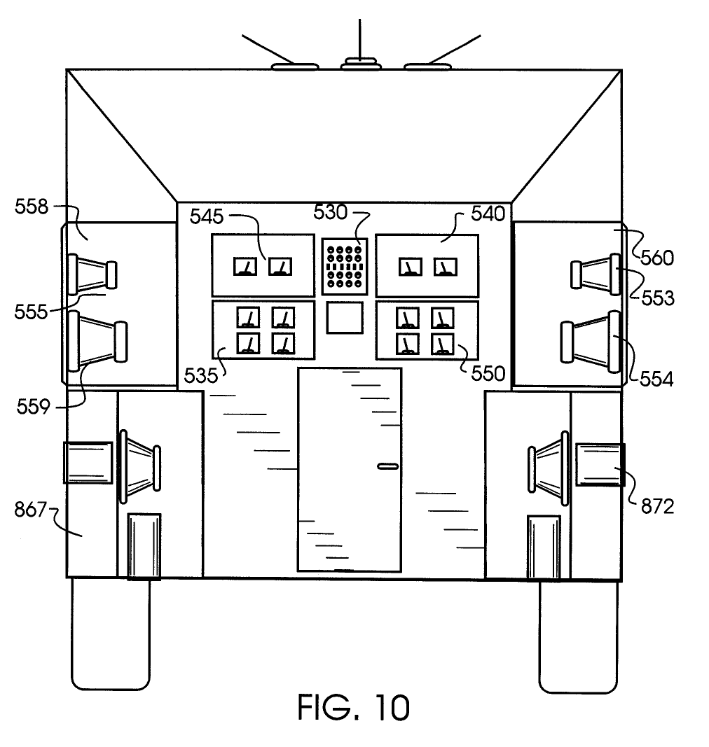

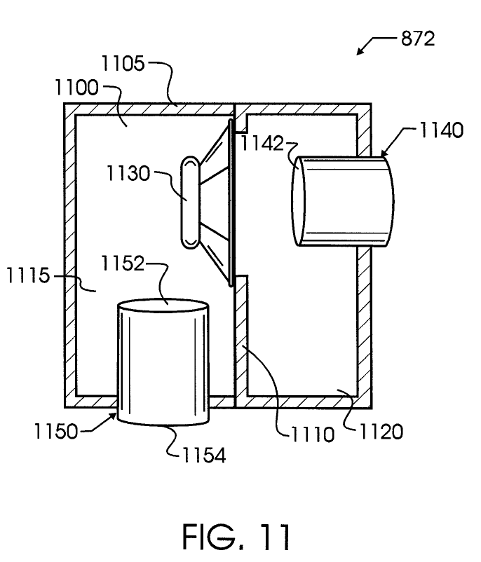

Figures 8 - 11 illustrate a somewhat more deluxe remote broadcasting system 800 which includes four sub-woofer speaker assemblies 866, 867, 871 and 872. As is evident in figure 10, the use of a larger truck for vehicle 110 provides substantially better access to each of the components. Nevertheless, a large truck requires greater initial capital to purchase and may not provide the appearance sought by all remote broadcasters. One sub-woofer 872 of the four sub-woofer speaker assemblies 866, 867, 871 and 872 is illustrated in much greater detail in figure 11. Therein it will be evident that cylindrical port 1140 passes directly from the front of driver 1130 out of compartment 1120 through assembly exterior wall 1105. Port 1140 has an opening 1142 within compartment 1120, and an opening 1144 which will most preferably pass beyond an exterior of vehicle 110. This port 1140 transmits low-frequency sound waves in a first direction from speaker box 110. A second port 1150 having openings 1152, 1154 is provided from the back side of driver 1130 in compartment 1115 and will transmit low-frequency sound waves through assembly exterior wall 1105 preferably beyond an exterior of vehicle 110. Port 1150 transmits most preferably in a second direction different from port 1140. This dual-direction transmission of low-frequency sound waves can be optimized with the geometry of vehicle 110 to provide strongly enhanced low-frequency output, such as is illustrated in figure 10 where speaker assembly 867 is ported through the left wall and floor, while speaker assembly 872 is ported through the right wall and floor.

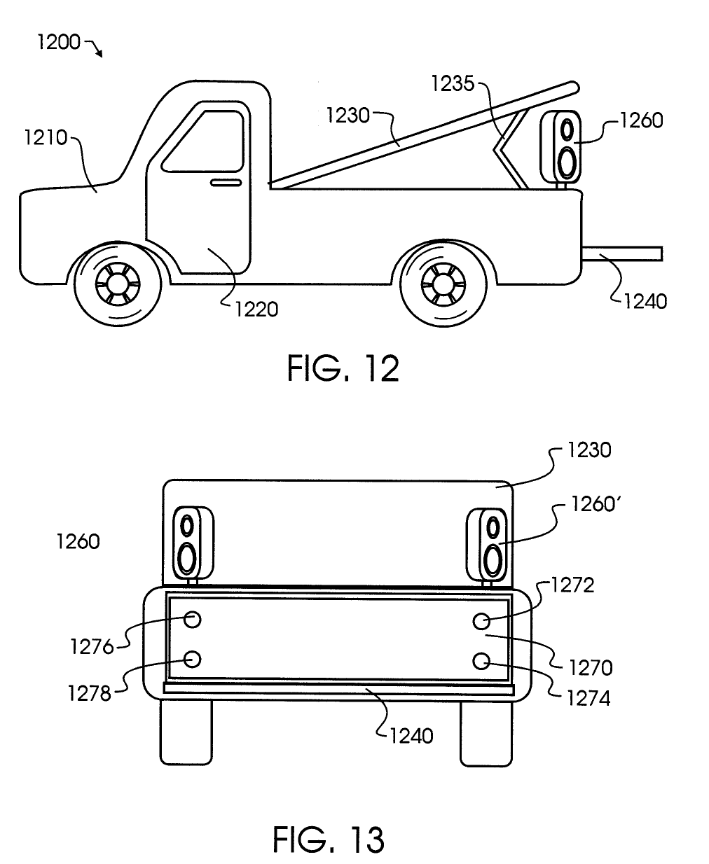

Figures 12 and 13 illustrate a second alternative embodiment remote broadcast system 1200 including a pick-up truck 1210 as the vehicle. Pick-up 1210 has a door 1220 for access into an interior compartment, which may house one or more of the audio components securely therein. Cover 1230 removably covers the cargo area. Cover 1230 may be elevated by brackets 1235, which may additionally include or incorporate springs and shock-absorbers as is known in the art. End gate 1240 raises and lowers in the ordinary fashion, and when lowered as shown in the figures opens access to sub-woofer assembly 1270, having ports 1272 - 1278 therein. Additional ports may be provided through the sides of the cargo box, the floor or end gate 1240, and these ports may be in addition to or instead of ports 1272 - 1278, similar to the ported sub-woofers of the earlier embodiments disclosed herein above. Speakers 1260 and 1260' are removably mounted to supports within the cargo area, such that speakers 1260, 1260' may be stored within the cargo area and secured under cover 1230 when not in use, and placed as shown in figures 12 and 123 during use. This second alternative embodiment 1200 does not offer all of the advantages of the preferred and first alternative embodiments described herein above, but nevertheless does expand the applicability of the present invention to alternative applications. Likewise, features that comprise each embodiment and known equivalents thereto may be used in combination with other embodiments. The present disclosure is not limited strictly to the specific embodiments illustrated herein but is instead open to an array of conceivable configurations. As is evident, in the earlier embodiments speaker assemblies 555 and 560 could be replaced by removable speakers similar to speakers 1260 and 1260', with the attendant requirement for mounting supports and electrical connectors to provide support and signal to the speaker assemblies.

While the foregoing details what is felt to be the preferred embodiment of the invention, no material limitations to the scope of the claimed invention are intended. Further, features and design alternatives that would be obvious to one of ordinary skill in the art are considered to be incorporated herein. For example, while the present system uses radio frequency transmissions from the microphone and remote, the use of an infra-red link such as a roof-mounted light waveguide or other transmission technique beyond radio is contemplated herein for the wireless components such as remote control and microphone. The scope of the invention is set forth and particularly described in the claims hereinbelow.

We claim:

An electrical audio processing system for processing a plurality of electrical source signals and converting said plurality of electrical source signals into an audio broadcast, said electrical audio processing system transported by a vehicle having an interior compartment surrounded by a vehicle exterior which protects said interior compartment from the vagaries of moisture, mud, dirt and debris during transport, comprising: a means for providing electricity to said electrical audio processing system; a means for selecting at least one input signal from said plurality of electrical source signals; a means for amplifying said selected at least one input signal; a means for dividing said at least one input signal into a plurality of frequency segregated output components; a means for converting a first one of said plurality of frequency segregated output components into a low frequency audible sound wave; and a means for selectively conducting low frequencies within said low frequency audible sound wave from said converting means through said vehicle exterior in a first direction while attenuating frequencies other than said low frequencies; whereby said low frequencies are conducted to said vehicle exterior without coupling to said vehicle.

The electrical audio processing system of claim 1 wherein said vehicle is self-propelled by a self-contained motive power system.

The electrical audio processing system of claim 2 wherein said means for providing electricity further comprises a means for inducing electricity from self-contained motive power system motive power and a means for distributing said induced electricity solely to said electrical audio processing system.

The electrical audio processing system of claim 3 further comprising a means for storing a sufficient quantity of said induced electricity for powering said electrical audio processing system through a broadcast of a coherent audio program without inducing additional electricity from said inducing means during said coherent audio program.

The electrical audio processing system of claim 1 further comprising a means for changing a second one of said plurality of frequency segregated output components into a high frequency audible sound-wave of frequency higher than said low frequency audible sound wave; and a means for selectively conducting high frequencies within said high frequency audible sound wave from said changing means through said vehicle exterior in a first direction.

The electrical audio processing system of claim 1 further comprising a second means for selectively conducting low-frequencies within said low frequency audible sound wave from said converting means through said vehicle exterior in a second direction different from said first direction.

The electrical audio processing system of claim 1 further comprising a means for controlling said amplifying means and said selecting means from a remote location to control said selecting and said amplifying.

The electrical audio processing system of claim 1 further comprising a means for forming an electrical signal from an audible sound; and a means for conveying said formed electrical signal to said selecting means to serve as a one of said plurality of electrical source signals.

The electrical audio processing system of claim 8 wherein said audible sound comprises a human voice, and said formed electrical signal is selected by said selecting means, whereby said human voice is amplified and broadcast through said vehicle exterior into public areas.

The electrical audio processing system of claim 8 wherein said forming and conveying means comprise a wireless diversity microphone.

A full-feature remote broadcast vehicle which is continuously setup and which is simultaneously secured against theft and vandalism in operation and while idle, comprising: a player mounted within said vehicle for converting a pre-recorded audio signal into a first electrical signal representative of said pre-recorded audio signal; a broadcast receiver mounted within said vehicle which receives broadcast signals representative of an audio program and converts said broadcast signals into a second electrical signal representative of said audio program; a microphone which transmits an electrical transmission signal generated by said microphone representative of an audible input to said microphone; a microphone transmission receiver mounted within said vehicle which receives said microphone transmission signal and converts said microphone transmission signal into a third electrical signal representative of said audible microphone input; an electrical source mounted within said vehicle for providing electrical energy; a remotely controlled selector switch mounted within said vehicle for selecting at least one of said first electrical signal, said second electrical signal and said third electrical signal as a selected input and passing said selected input through to an output; a loudspeaker mounted within said vehicle for converting said selector switch output to an audible sound wave; a port coupled from said loudspeaker through said vehicle exterior which emanates said audible sound wave exterior to said vehicle in a first direction and which selectively enhances a narrow bandwidth of said low frequency audible sound wave; and a remote control which receives human input from a point removed from said broadcast vehicle and responsive thereto variably controls said remotely controlled selector switch.

The remote broadcast vehicle of claim 11 further comprising an infra-red communications link between said remote control and said remotely controlled selector switch.

The remote broadcast vehicle of claim 11 wherein said port comprises a tuned port which selectively enhances a narrow low frequency bandwidth of said audible sound wave.

The remote broadcast vehicle of claim 13 further comprising additional loudspeakers mounted within said remote broadcast vehicle for converting electrical signals into additional audible sound waves; and additional tuned ports for coupling said additional audible sound waves through said vehicle exterior which selectively enhance additional narrow bandwidths.

The remote broadcast vehicle of claim 13 further comprising a second tuned port coupled from said converting means through said vehicle exterior which emanates said low frequency audible sound wave exterior to said vehicle in a second direction different from said first direction.

The remote broadcast vehicle of claim 11 further comprising an up-link mounted within said vehicle for transmitting said selector switch output to a central broadcast facility for further retransmission therefrom.

The remote broadcast vehicle of claim 11 wherein said electrical source comprises an electrical alternator which is isolated from an electrical system used by said vehicle for traffic signaling.

The remote broadcast vehicle of claim 11 further comprising a battery bank mounted within said vehicle for storing said electrical energy.

The remote broadcast vehicle of claim 11 wherein said player is selected from a CD player, a tape player and a DVD player.

The remote broadcast vehicle of claim 11 wherein said broadcast receiver further comprises a broadcast radio receiver.

The remote broadcast vehicle of claim 11 wherein said microphone transmission receiver receives said electrical transmission signal without wires through at least two reception paths.

The combination of a speaker for converting electrical signals to audible sounds and a vehicle having an exterior body forming an enclosed space within said vehicle and having access portals through which a human may pass for entry into said enclosed space and exit therefrom, wherein the improvement comprises: a cross-over for dividing said electrical signals into a low frequency component and a high frequency component of relatively higher frequency than said low frequency component; a speaker housing enclosing said speaker and blocking emanation of audible sounds directly from said speaker into an ambient exterior to said speaker housing; and a tuned port for selectively transmitting a limited bandwidth of said audible sounds from said enclosed space through said exterior vehicle body.

The combination of a speaker and a vehicle of claim 22 further comprising a second tuned port for selectively transmitting a limited bandwidth of said audible sounds from said enclosed space through said exterior vehicle body.

The combination of a speaker and a vehicle of claim 23 wherein said second tuned port transmits said audible sounds in a direction different from said first tuned port.

The combination of a speaker and a vehicle of claim 24 further comprising a third tuned port for selectively transmitting a limited bandwidth of said audible sounds from said enclosed space through said exterior vehicle body in a direction different from said first and second tuned ports.
